(19) United States
(12) Patent Application Publication
(10) Pub. No.: US 2020/0095116 A1
(43) Pub. Date: Mar. 26, 2020

(54) MEMS TRANSDUCER PACKAGE AND A MEMS DEVICE INCLUDING THE SAME

(71) Applicant: Seoul National University R&DB Foundation, Seoul (KR)

(72) Inventors: Junsoo CHO, Seoul (KR); Suhwan KIM, Seoul (KR)

(73) Assignee: Seoul National University R&DB Foundation, Seoul (KR)

(21) Appl. No.: 16/698,795

(22) Filed: Nov. 27, 2019

Related U.S. Application Data
(63) Continuation of application No. PCT/KR2018/004624, filed on Apr. 20, 2018.

(30) Foreign Application Priority Data
May 30, 2017 (KR) 10-2017-0066679

(51) Int. Cl. B81B 7/00

(52) U.S. Cl. CPC B81B 7/007; B81B 7/0061; B81B 2207/015; B81B 2203/0127; B81B 7/0064

(57) ABSTRACT

A microelectromechanical sensors (MEMS) device includes a first substrate, a MEMS transducer package attached on the first substrate and including a MEMS transducer therein configured to output an electrical signal corresponding to movement of fluid, and a semiconductor device attached on the first substrate and configured to process the electrical signal provided from the MEMS transducer.

### CROSS-REFERENCE TO RELATED APPLICATIONS

This application is a continuation of and claims priority to PCT application No. PCT/KR2018/004624, filed on Apr. 20, 2018, which claims priority to Korean Patent Application No. 10-2017-0066679, filed on May 30, 2017, which is incorporated herein by reference in its entirety.

### BACKGROUND

### 1. Technical Field

Various embodiments generally relate to a microelectromechanical systems (MEMS) transducer package and a MEMS device including the MEMS transducer package and more particularly to a MEMS transducer package including a MEMS transducer therein and a signal from the MEMS transducer is provided to a semiconductor chip located out of the MEMS transducer package and a MEMS device including the MEMS transducer package.

### 2. Related Art

FIG. 1 shows a cross-sectional view of a MEMS device according to a conventional art.

The conventional MEMS device includes a substrate 30, a transducer 10 attached on the substrate 30, a semiconductor chip 20, and a case 40.

The transducer 10 and the semiconductor chip 20 is electrically coupled via a conductive wire 21 and the semiconductor chip 20 and the substrate 30 is electrically coupled via a conductive wire 22.

The transducer 10 includes a diaphragm 11 and an inner space 12.

In the conventional MEMS device, a passage 41 is formed on the case 40.

In the conventional MEMS device, air introduced from the passage 41 formed in the case 40 of the transducer causes vibration to the diaphragm 11 of the transducer 10 and makes the movement of the diaphragm 11 be converted into an electrical signal.

The electrical signal is processed in the semiconductor chip 20 and output to the outside.

The conventional MEMS device includes a MEMS transducer package including a MEMS transducer 10 and a semiconductor chip 20 packaged together in a space between the case 40 and the substrate 30.

In the conventional MEMS device, an area may increase when one semiconductor chip 20 processes signals of a plurality of MEMS transducers 10.

Accordingly, there is a limit in improving the performance of the semiconductor device 20 included in the conventional MEMS device.

In addition, the conventional MEMS device has a limitation in implementing various functions by increasing the area of the semiconductor chip 20 or increasing the number of MEMS transducers 10.

### SUMMARY

In accordance with the present teachings, an microelectromechanical systems (MEMS) device may include a first substrate, a MEMS transducer package attached on the first substrate and including a MEMS transducer therein configured to output an electrical signal corresponding to movement of fluid, and a semiconductor device attached on the first substrate and configured to process the electrical signal provided from the MEMS transducer.

In accordance with the present teachings, an microelectromechanical systems (MEMS) transducer package may include a second substrate, a MEMS transducer attached on the second substrate and configured to generate an electrical signal corresponding to movement of fluid, and a case attached on the second substrate so that a space between the second substrate be formed and the MEMS transducer is located within the space, wherein the second substrate comprises a second conductive line to output an electrical from the MEMS transducer to outside.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed novelty, and explain various principles and advantages of those embodiments.

FIG. 1 shows a cross-sectional view of a MEMS device according to a conventional art

FIGS. 2 to 15 show cross-sectional views of MEMS devices according to various embodiments of the present disclosure.

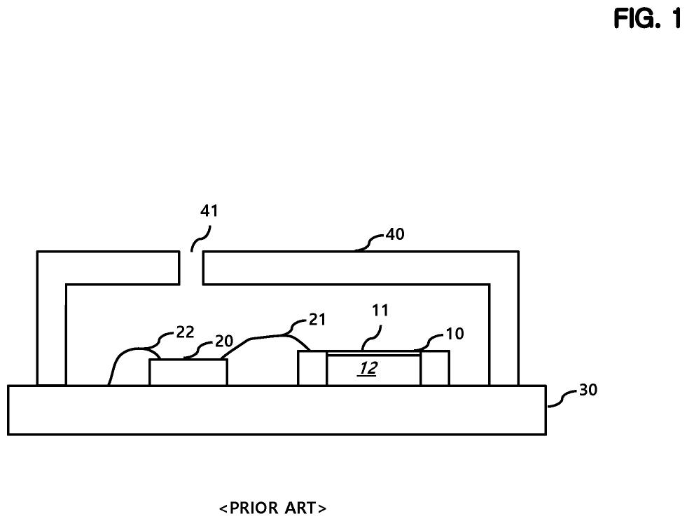

### DETAILED DESCRIPTION

The following detailed description references the accompanying figures in describing embodiments consistent with this disclosure. The examples of the embodiments are provided for illustrative purposes and are not exhaustive. Additional embodiments not explicitly illustrated or described are possible. Further, modifications can be made to presented embodiments within the scope of the present teachings. The detailed description is not meant to limit this disclosure. Rather, the scope of the present disclosure is defined only in accordance with the presented claims and equivalents thereof.

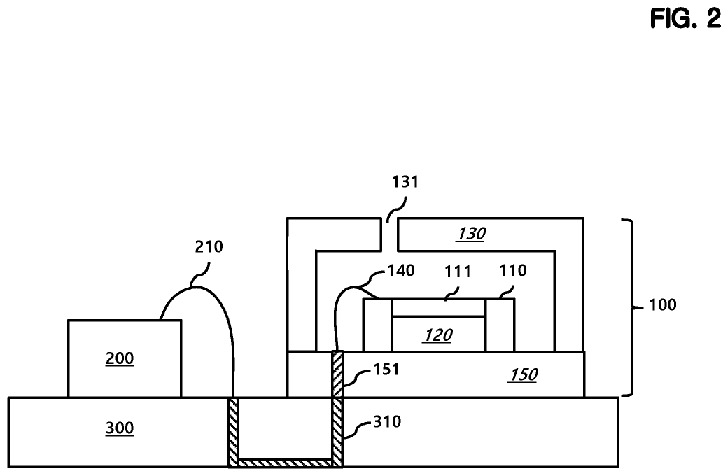

FIG. 2 show a cross-sectional view of a MEMS device according to an embodiment of the present disclosure.

A MEMS device according to an embodiment of the present disclosure includes a MEMS transducer package 100, a semiconductor chip 200, and a first substrate 300.

The MEMS transducer package 100 and the semiconductor chip 200 may be attached on the first substrate 300.

The MEMS transducer package 100 and the semiconductor chip 200 are electrically coupled to each other through the first conductive wire 210 and the first conductive line 310 formed in the first substrate 300.

The MEMS transducer package 100 includes a MEMS transducer 110, a case 130, and a second substrate 150.

The MEMS transducer 110 may perform various functions such as a microphone, a pressure sensor, a speed sensor, and the like that outputs an electrical signal corresponding to movement of fluid.

In this embodiment, the MEMS transducer 110 operates as a microphone, and may be implemented as a capacitive microphone or a piezoelectric microphone.

The MEMS transducer 110 includes a membrane structure 111.

In the case of a capacitive microphone, the membrane structure 111 may include a diaphragm in which permanent charge is charged. In the case of a piezoelectric microphone, the membrane structure 111 may include a diaphragm comprising a piezoelectric material.

In other embodiments, additional elements may be added to the membrane structure 111.

For example, a support that can be variously designed and modified to mechanically fix the membrane structure 111 to the wall of the MEMS transducer 110, a transmission element that can be variously modified according to a method for transmitting an electrical signal, and the like may be added.

In this embodiment, the MEMS transducer 110 is mounted on the second substrate 150.

The MEMS transducer 110 is electrically coupled to the first conductive line 310 of the first substrate 300 through the second conductive wire 140 and the second conductive line 151 formed in the second substrate 150.

The MEMS transducer 110 includes an inner space 120 formed between the second substrate 150 and the membrane structure 111.

The case 130 is attached to an upper portion of the second substrate 150 and includes the MEMS transducer 110 and a second conductive wire 140 therein.

In this embodiment, the case 130 includes a case passage 131 at the upper portion and sound waves are transmitted through the case passage 131.

Sound waves transmitted through the case passage 131 may cause deformation of the membrane structure 111, and corresponding electrical signals may be transmitted via the second conductive wire 140, the second conductive line 151, the first conductive wire 310, and the first conductive line 310 to the semiconductor chip 200 and may be processed at the semiconductor chip 200.

In the present disclosure, the MEMS transducer package 100 includes the MEMS transducer 110 therein but does not include the semiconductor chip 200.

Therefore, the MEMS transducer package 100 may be further miniaturized as compared with the prior art, and the semiconductor chip 200 may increase an area for improving performance without being limited by the size of the MEMS transducer package 100.

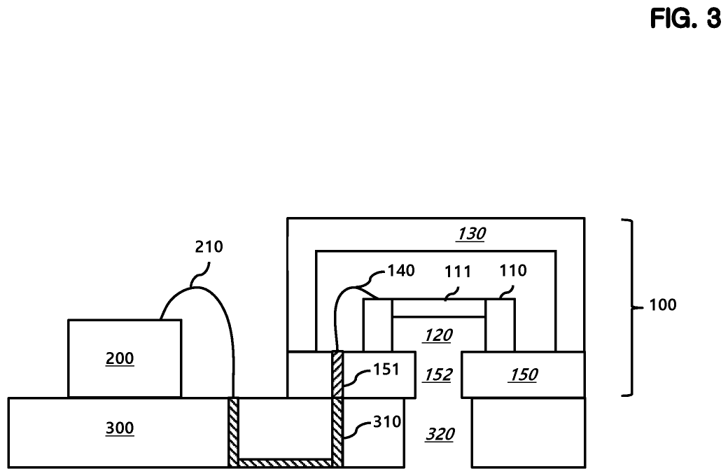

FIGS. 3 to 15 are cross-sectional views of MEMS devices according to various embodiments of the present disclosure.

Each of MEMS devices shown in FIGS. 3 to 5 does not include a case passage above the MEMS transducer package 100 but includes a second substrate passage 152 below the MEMS transducer package 100.

The second substrate passage 152 is formed in the second substrate 150 to open the inner space 120 of the MEMS transducer 110 to the outside.

In addition, the first substrate 300 includes a first substrate passage 320 that opens the second substrate passage 152 of the second substrate 150 to the outside.

Sound waves transmitted through the first substrate passage 320 and the second substrate passage 152 cause deformation of the membrane structure 111, and a corresponding electrical signal are transmitted via the second conductive wire 140, the second conductive line 151, the first conductive line 310, and the first conductive wire 210 to the semiconductor chip 200 and may be processed at the semiconductor chip 200.

FIGS. 3 to 5 illustrate embodiments that are distinguished according to the relative sizes of the second substrate passage 152 and the first substrate passage 320.

In the embodiment of FIG. 3, the diameter of the second substrate passage 152 is smaller than the diameter of the first substrate passage 320.

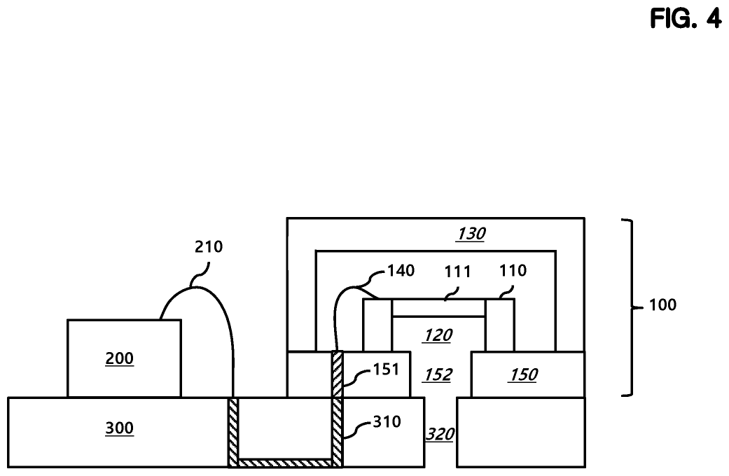

In the embodiment of FIG. 4, the diameter of the second substrate passage 152 is larger than the diameter of the first substrate passage 320.

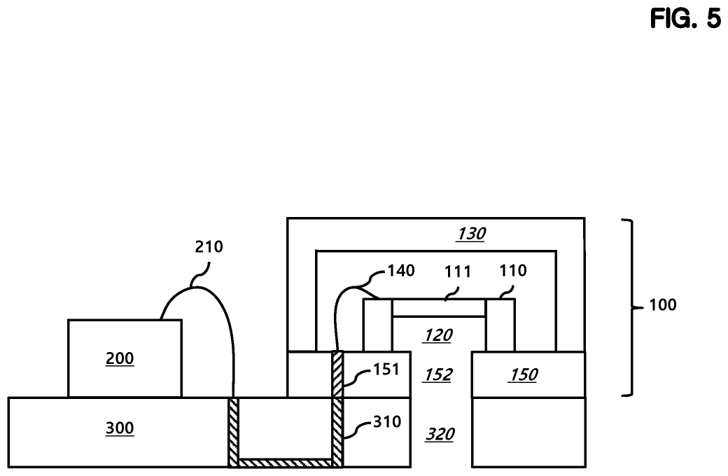

In the embodiment of FIG. 5, the diameter of the second substrate passage 152 is equal to the diameter of the first substrate passage 320.

In FIGS. 3 to 5, there are illustrated various embodiments according to diameters of the second substrate passage and the first substrate passage, but various design changes may be made in terms of the number of holes in each passage, the shape of the passages, and the like.

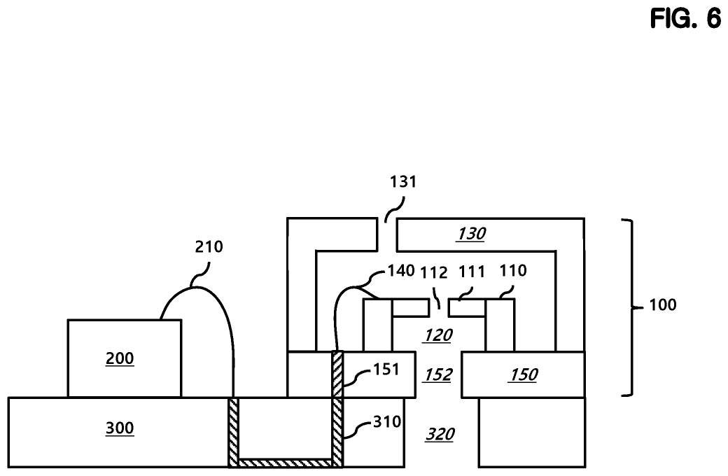

FIG. 6 illustrates an embodiment where a case passage 131 is formed at an upper portion of the MEMS transducer package 100 and a second substrate passage 152 is formed at a lower portion of the MEMS transducer package 100.

That is, the embodiment of FIG. 6 may be viewed as an embodiment in which the embodiments of FIG. 2 and FIG. 3 are combined.

However, in the embodiment of FIG. 6, the membrane passage 112 may be additionally provided in the membrane structure 111.

In this case, sound waves introduced through the first to membrane passages may be mixed in the inner space 120 of the MEMS transducer 100, and the MEMS transducer 100 may output an electrical signal corresponding to the mixed sound waves to a semiconductor chip 200.

In another case, the MEMS transducer 100 may output an electrical signal corresponding to the flow of the fluid passing through the first to membrane passages. In this case, the MEMS transducer 100 may output an electrical signal corresponding to the velocity, pressure, or the like of the fluid.

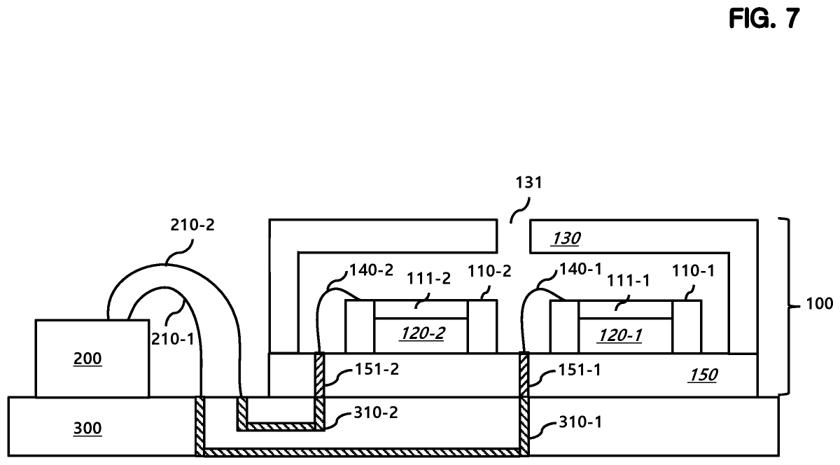

FIG. 7 illustrates an embodiment in which two MEMS transducers 110-1 and 110-2 are disposed in one MEMS transducer package 100.

Accordingly, the first conductive wires 210-1 and 210-2, the second conductive wires 140-1 and 140-2, the first conductive lines 310-1 and 310-2, and the second conductive lines 151-1 and 151 -2 are provided corresponding to the number of MEMS transducers 110-1 and 110-2.

As described above, the MEMS device according to the present embodiment may process output signals provided from two or more MEMS transducers 110-1 and 110-2 included in one MEMS transducer package 100 at the semiconductor chip 200 which is out of the MEMS transducer package 100.

In the embodiment of FIG. 7, the MEMS transducers 110-1 and 110-2 may perform the same function or may perform different functions. In addition, the sensing range may be designed to be different even when performing the same function.

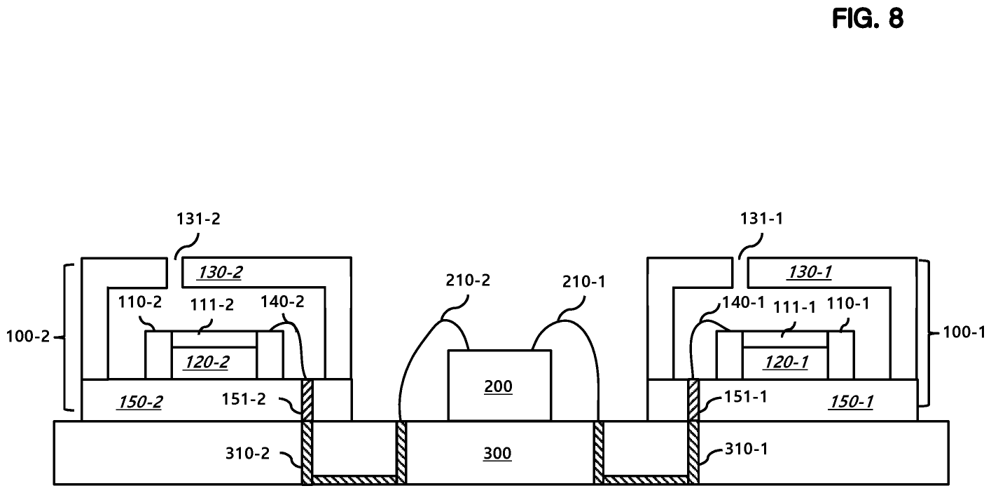

FIG. 8 illustrates a MEMS device including two or more MEMS transducer packages 100-1 and 100-2.

Accordingly, a plurality of first conductive wires 210-1 and 210-2 and first conductive lines 310-1 and 310-2 are provided in correspondence with the number of MEMS transducer packages 100-1 and 100-2.

FIG. 8 illustrates an embodiment where one MEMS transducer 110-1 and 110-2 is disposed inside one MEMS transducer package 100-1 and 100-2, but as shown in FIG. 7, one MEMS transducer package may include two or more MEMS transducers therein.

In this case, the number of the first conductive wires and the first conductive lines may increase correspondingly.

In FIGS. 2 to 8, embodiments in which the MEMS transducer package 100 including the second substrate 150 is mounted on the first substrate 300 together with the semiconductor chip 200 are disclosed.

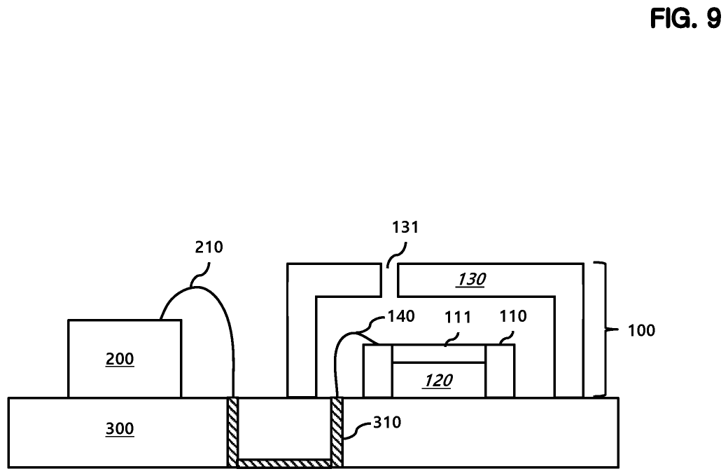

In FIGS. 9 to 13, embodiments in which the MEMS transducer package 100 is directly formed on the first substrate 300 without including the second substrate 150 are disclosed.

Embodiments shown in FIGS. 9 to 13 may be advantageous when the MEMS transducer package is manufactured during the manufacturing process of the MEMS device.

The embodiment of FIG. 9 corresponds to the embodiment of FIG. 2.

In the embodiment of FIG. 9, the MEMS transducer package 100 may be formed on the first substrate 300.

Accordingly, the MEMS transducer 110 may be mounted on the first substrate 300 to form an inner space 120 between the first substrate 300 and the membrane structure 111.

In addition, the second conductive wire 140 is directly coupled to the first conductive line 310.

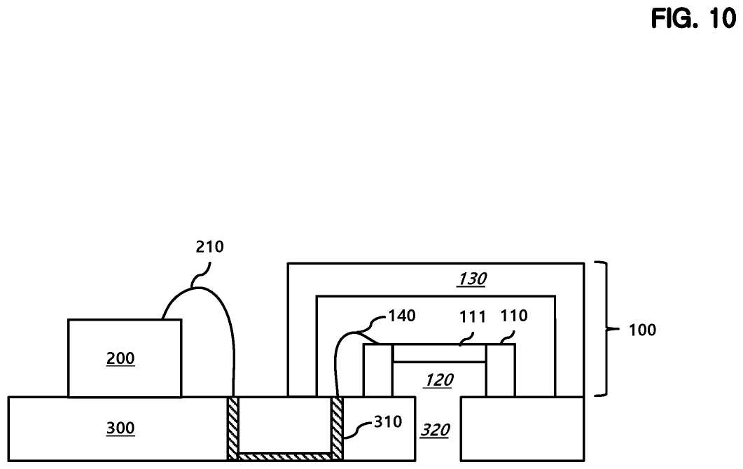

The embodiment of FIG. 10 corresponds to the embodiment of FIG. 3.

In FIG. 10, a passage is not formed in the case 130, and a first substrate passage 320 is formed in the first substrate 300.

Accordingly, the inner space 120 may be opened to the outside through the first substrate passage 320.

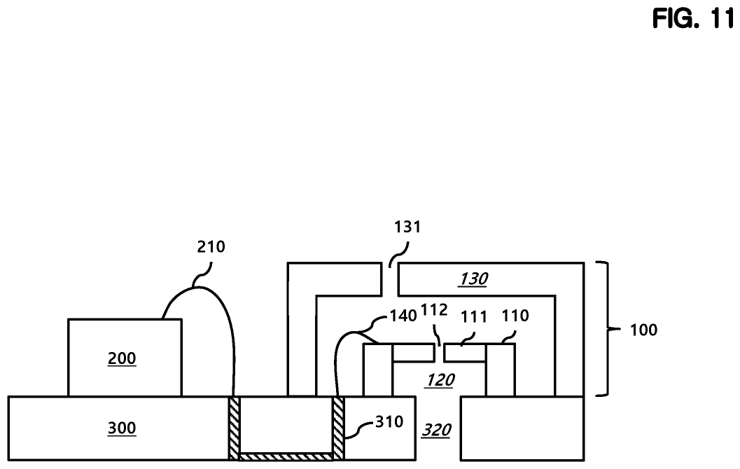

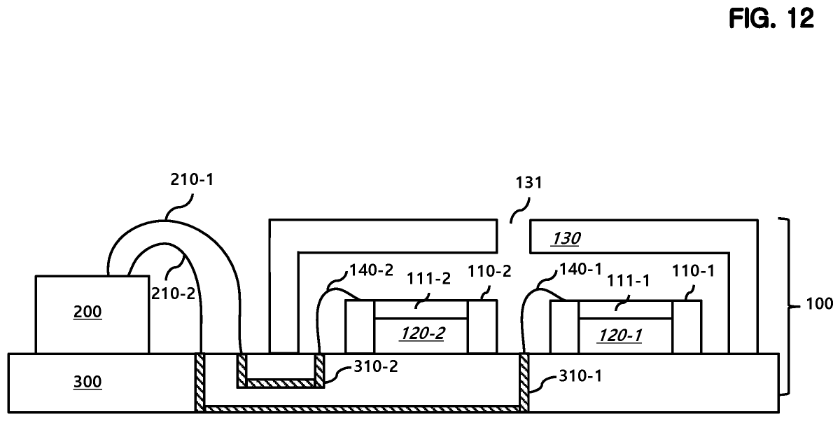

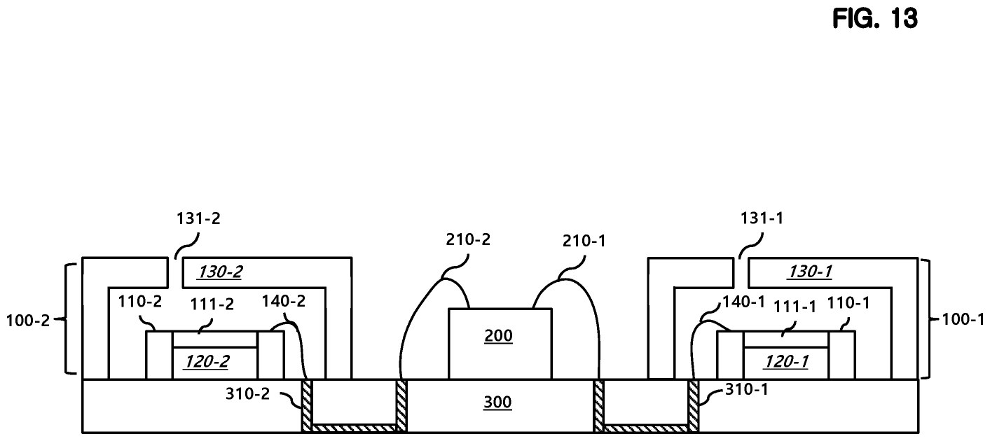

The embodiment of FIG. 11 corresponds to the embodiment of FIG. 6, the embodiment of FIG. 12 corresponds to the embodiment of FIG. 7, and the embodiment of FIG. 13 corresponds to the embodiment of FIG. 8.

In the embodiments shown. in FIGS. 11 to 13, the MEMS transducer package 100, 100-1, 100-2 may be directly attached on the first substrate 300 without the second substrate 150, 150-1, 150-2 interposed therebetween, which is different from the embodiments of FIGS. 6 to 8.

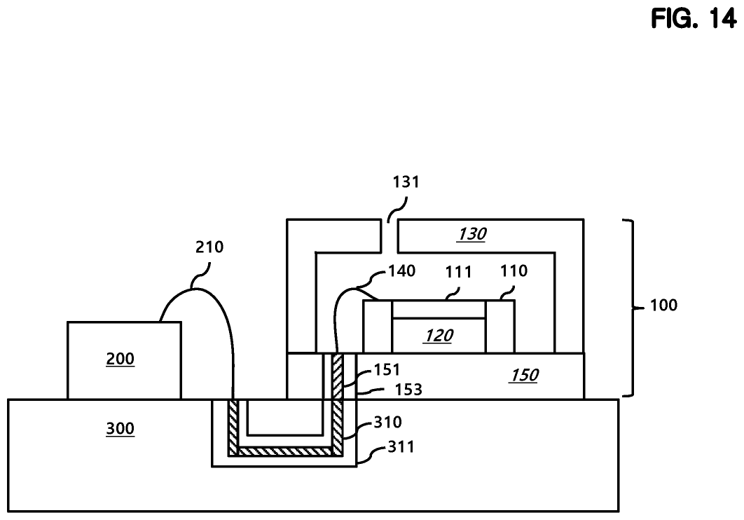

FIG. 14 is a cross-sectional view of a MEMS device according to an embodiment of the present disclosure.

In the embodiment of FIG. 14, the first substrate 300 further includes a first shield layer 311 formed around the first conductive line 310.

The electrical signal output from the MEMS transducer 110 is very minute and it may be distorted outside the MEMS transducer package 100.

Accordingly, the first shield layer 311 is further provided around the first conductive line 310 of the first substrate 300 to shield the electromagnetic signal flowing from the outside, thereby distortion of a signal output from the MEMS transducer 110 can be reduced.

In another embodiment, a second shield layer 153 may be further provided around the second conductive line 151 of the second substrate 150 included in the MEMS transducer package 100 to shield electromagnetic signals from the outside.

The first shield layer 311 and the second shield layer 153 may have a linear or planar structure.

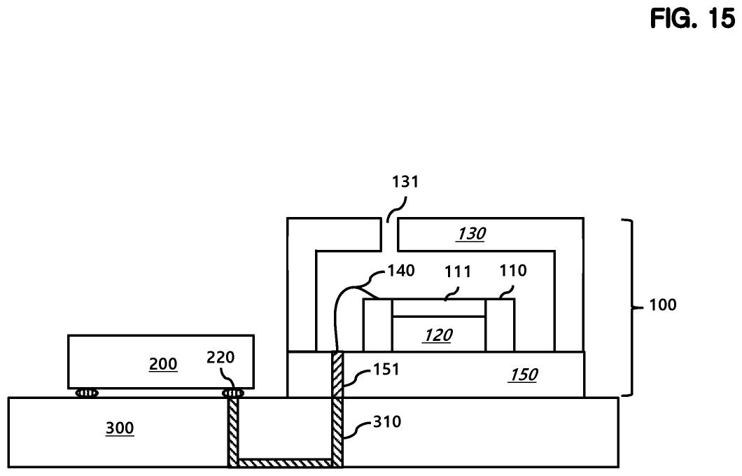

FIG. 15 is a cross-sectional view of a MEMS device according to an embodiment of the present disclosure.

In FIG. 15, the semiconductor chip 200 may be mounted on the first substrate 300 in a surface mount manner.

Accordingly, the semiconductor chip 200 may be electrically coupled to the first conductive line 310 of the first substrate 300 through the solder bumps 220 instead of the first conductive wire 210.

Although various embodiments have been described for illustrative purposes, it will be apparent to those skilled in the art that various changes and modifications may be made to the described embodiments without departing from the spirit and scope of the disclosure as defined by the following claims.

What is claimed is:

1. A microelectromechanical sensors (MEMS) device comprising:
a first substrate;
a MEMS transducer package attached on the first substrate and including a MEMS transducer therein configured to output an electrical signal corresponding to movement of fluid; and
a semiconductor device attached on the first substrate and configured to process the electrical signal provided from the MEMS transducer.

2. The MEMS device of claim 1, wherein the MEMS transducer package covers the MEMS transducer so that the semiconductor chip and the MEMS transducer be located in separate spaces.

3. The MEMS device of claim 2, wherein the MEMS transducer package further comprises a conductive wire for electrically coupling the MEMS transducer with the first substrate.

4. The MEMS device of claim 2, wherein the MEMS transducer package further comprises a second substrate being interposed between the MEMS transducer package and the first substrate, and
wherein the second substrate includes a conductive line configured to transmit an electrical signal provided from the MEMS transducer to the first substrate.

5. The MEMS device of claim 2, wherein the MEMS transducer package includes a case passage formed in the case or a first substrate passage formed on the first substrate to open an inner space of the MEMS transducer to outside.

6. The MEMS device of claim 5, wherein the MEMS transducer includes a membrane structure configured to generate an electrical signal according to fluid introduced through the case passage or the first substrate passage.

7. The MEMS device of claim 6, wherein the MEMS transducer package includes the case passage and the first substrate passage and further includes a membrane passage, wherein the membrane structure moves according to movement of fluids introduced via the case passage, the first substrate passage and the membrane passage.

8. The MEMS device of claim 5, wherein the MEMS transducer package further comprises a second substrate being interposed between the MEMS transducer and the first substrate,
wherein the second substrate further comprises a conductive line for transferring an electrical signal from the MEMS transducer to the first substrate and a second substrate passage for opening an inner space of the MEMS transducer to the first substrate passage.

9. The MEMS device of claim 1, wherein the MEMS transducer package further comprises one or more MEMS transducers each provides an electrical signal to the semiconductor chip.

10. The MEMS device of claim 1, further comprises one or more additional MEMS transducer packages each including a MEMS transducer therein for providing an electrical signal to the semiconductor chip.

11. The MEMS device of claim 1, wherein the first substrate comprises a first conductive line for providing an electrical signal from the MEMS transducer to the semiconductor chip.

12. The MEMS device of claim 11, wherein the first substrate further comprises a first shied layer around the first conductive line.

13. The MEMS device of claim 1, wherein the semiconductor chip is electrically coupled to the first substrate via a solder bump or a first conductive wire.

14. A microelectromechanical sensors (MEMS) transducer package comprising:
a second substrate;
a MEMS transducer attached on the second substrate and configured to generate an electrical signal corresponding to movement of fluid; and
a case attached on the second substrate so that a space between the second substrate be formed and the MEMS transducer is located within the space,
wherein the second substrate comprises a second conductive line to output an electrical from the MEMS transducer to outside.

15. The MEMS transducer package of claim 14, further comprising a case passage formed at the case to open the MEMS transducer to outside or a second substrate passage formed at the second substrate to open an inner space of the MEMS transducer to outside.

16. The MEMS transducer package of claim 15, wherein the MEMS transducer comprises a membrane structure moving according to movement of fluid introduced through the case passage or the second substrate passage.

17. The MEMS transducer package of claim 16, further comprising a membrane passage in the membrane structure, and
wherein the membrane structure moves according to fluid moving through the case passage, the second substrate passage and the membrane passage.

18. The MEMS transducer package of claim 14, wherein the second substrate further comprises a second shield layer around the second conductive line.
